(19) United States
(12) Patent Application Publication
(10) Pub. No.: US 2012/0134079 A1
(43) Pub. Date: May 31, 2012

(54) FILM, HOUSING USING THE FILM, AND METHOD FOR MANUFACTURING THE HOUSING

(75) Inventor: KAI-RONG LIAO, Shenzhen (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/031,714

(22) Filed: Feb. 22, 2011

(30) Foreign Application Priority Data
Nov. 25, 2010 (CN) 201010559077.4

(51) Int. Cl. H05K 5/00; B29C 45/16

(52) U.S. Cl. 361/679.01; 264/513

(57) ABSTRACT

A housing for an electronic device includes a decorative film being tubular and including a substrate and a shading layer attached on a portion of an exterior surface of the substrate, an area of the decorative film which is not shielded by the shading layer defining a displaying section. A tubular main body is formed surrounding an outer surface of the decorative film by insert molding process.

### BACKGROUND

1. Technical Field

The disclosure relates to films, housings using the films and methods for manufacturing the housings.

2. Description of Related Art

A typical housing of electronic devices includes an upper element and a lower element. The upper element and the lower element are separately molded by injection molding, and then are connected together by some means such as a latching mechanism. However, a gap may be formed between the upper element and the lower element affecting the appearance of the housing. Additionally, pollutants may enter the housing through the gap.

Therefore, there is room for improvement within the art.

### BRIEF DESCRIPTION OF THE DRAWINGS

Many aspects of the exemplary housing and method for manufacturing the housing can be better understood with reference to the following drawings. These drawings are not necessarily drawn to scale, the emphasis instead being placed upon clearly illustrating the principles of the exemplary film, housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 is a schematic view of a housing according to an exemplary embodiment.

FIG. 2 is a cross-sectional view of the housing in FIG. 1.

FIG. 3 is a cross-sectional of an exemplary mold for manufacturing the housing in FIG. 1.

### DETAILED DESCRIPTION

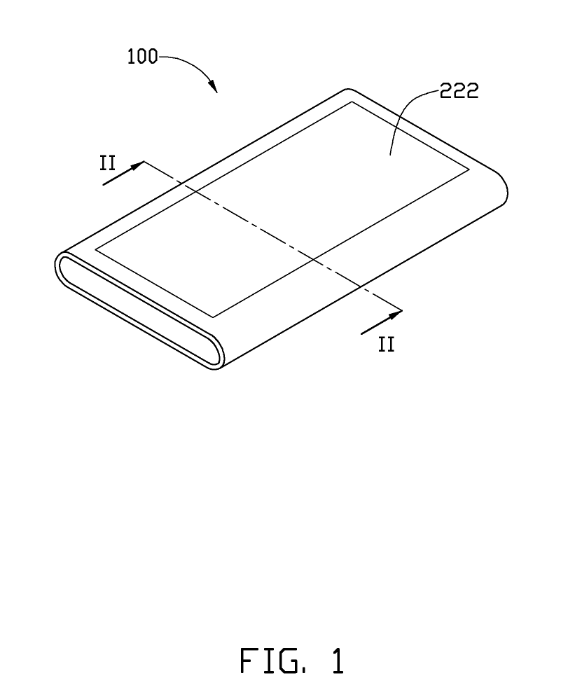

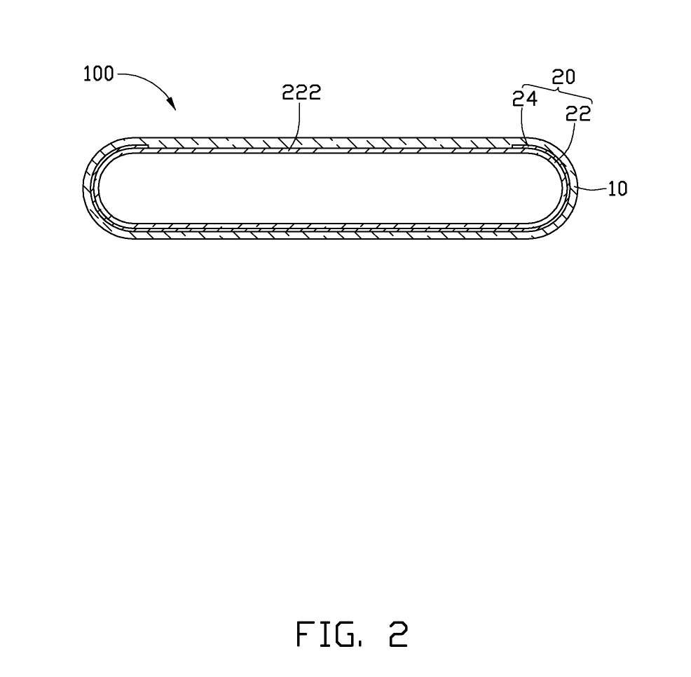

An exemplary embodiment of housing 100 is shown in FIGS. 1 and 2. The housing 100 may be used for an electronic device, such as a mobile phone. The housing 100 includes a main body 10 and a decorative film 20. The decorative film 20 is formed on an inner surface of the main body 10.

The main body 10 is tubular and surrounds an outer surface of the decorative film 20. The main body 10 may be transparent thermoplastic, such as one selected from a group of polycarbonate, polymethyl methacrylate, acrylonitrile butadiene styrene, and polystyrene. The decorative film 20 is also tubular and includes a substrate 22 and a shading layer 24 formed on the substrate 22. The substrate 22 is transparent thermoplastic, such as one selected from a group of polycarbonate, polymethyl methacrylate, acrylonitrile butadiene styrene, and polystyrene. The shading layer 24 is opaque ink. The shading layer 24 is attached on a portion of an exterior surface of the substrate 22, to define a displaying section 222 on an area of the decorative film 20 which is not shielded by the shading layer 24.

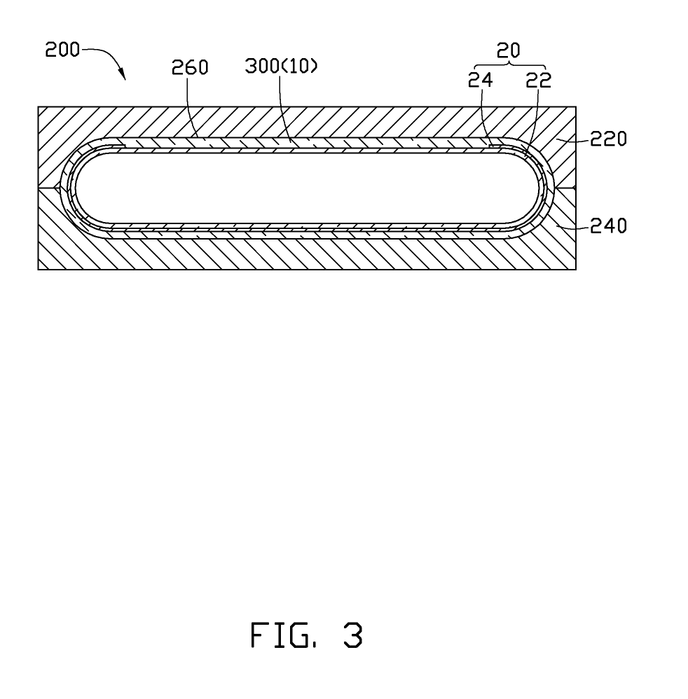

Referring to FIGS. 2-3, a method for manufacturing the housing 100 may include at least the following steps.

A decorative film 20 is provided. The decorative film 20 is tubular and includes a substrate 22 and a shading layer 24 formed on a surface of the substrate 22. The decorative film 20 may be molded by a blow molding process. The thickness of the substrate 22 can be about 0.17 millimeters to 0.23 millimeters. The substrate 22 is transparent thermoplastic, such as one selected from a group of polycarbonate, polymethyl methacrylate, acrylonitrile butadiene styrene, and polystyrene. The shading layer 24 may be opaque ink. The shading layer 24 is attached on a portion of an exterior surface of the substrate 22. An area of the decorative film 20 not shielded by the shading layer 24 defines a displaying section 222.

A mold 200 is provided. The mold 200 includes a male mold 220 and a female mold 240, that together cooperatively define a mold cavity 260. The mold cavity 260 has the same shape and size as the housing 100.

The decorative film 20 is positioned in the mold 200, and a gap 300 is formed between the mold 200 and the decorative film 20 corresponding to the main body 10.

Liquid transparent thermoplastic is injected into the mold cavity 260 to fill the gap 300 thereby forming the main body 10 on the substrate 22 to manufacture a housing 100. The liquid transparent thermoplastic may be one selected from a group of polycarbonate, polymethyl methacrylate, acrylonitrile butadiene styrene, and polystyrene.

In this disclosure, the decorative film 20 will have an attractive, three-dimensional appearance when viewed through the main body 10.

It is to be understood, however, that even through numerous characteristics and advantages of the exemplary embodiments have been set forth in the foregoing description, together with details of the structure and function of the invention, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing for an electronic device, comprising:
a tubular decorative film, the decorative film including a substrate and a shading layer formed on a portion of an exterior surface of the substrate, an area of the decorative film not shielded by the shading layer defines a displaying section; and
a tubular main body surrounding an outer surface of the decorative film by insert molding process.

2. The housing as claimed in claim 1, wherein the main body is transparent thermoplastic.

3. The housing as claimed in claim 2, wherein the thermoplastic is one selected from a group of polycarbonate, polymethyl methacrylate, acrylonitrile butadiene styrene, and polystyrene.

4. The housing as claimed in claim 1, wherein the substrate is transparent thermoplastic.

5. The housing as claimed in claim 4, wherein the thermoplastic is one selected from a group of polycarbonate, polymethyl methacrylate, acrylonitrile butadiene styrene, and polystyrene.

6. The housing as claimed in claim 1, wherein the shading layer is opaque ink.

7. A tubular decorative film, comprising:
a substrate; and
a shading layerformed on a portion of an exterior surface of the substrate, to define a displaying section on an area of the decorative film which is not shielded by the shading layer.

8. The decorative film as claimed in claim 7, wherein the substrate is transparent thermoplastic.

9. The decorative film as claimed in claim 8, wherein the thermoplastic is one selected from a group of polycarbonate, polymethyl methacrylate, acrylonitrile butadiene styrene, and polystyrene.

10. The decorative film as claimed in claim 7, wherein the shading layer is opaque ink.

11. A method for manufacturing a housing of an electronic device, comprising:
providing a decorative film, the decorative film being tubular and including a substrate and a shading layer attached on a portion of an exterior surface of the substrate, an area of the decorative film not shielded by the shading layer defining a displaying section;
providing a mold defining a mold cavity;
inserting the decorative film in the mold cavity to form a gap between the decorative film and the mold;
injecting liquid transparent thermosetting plastic into the gap;
curing the transparent thermosetting plastic to form a main body on an outer surface of the decorative film.

12. The method as claimed in claim 11, wherein the decorative film is molded by blow molding process.

13. The method as claimed in claim 11, wherein the thickness of the substrate is about 0.17 millimeters to 0.23 millimeters.

14. The method as claimed in claim 11, wherein the substrate is transparent thermoplastic.

15. The method as claimed in claim 14, wherein the transparent thermoplastic is one selected from a group of polycarbonate, polymethyl methacrylate, acrylonitrile butadiene styrene, and polystyrene.

16. The method as claimed in claim 11, wherein the shading layer is opaque ink.
